(19) United States
(12) Patent Application Publication
(10) Pub. No.: US 2020/0341589 A1
(43) Pub. Date: Oct. 29, 2020

(54) TOUCH SCREEN ASSEMBLY, METHOD OF MANUFACTURING TOUCH SCREEN ASSEMBLY AND TOUCH DEVICE

(71) Applicant: Wuhan China Star Optoelectronics Semiconductor Display Technology Co., Ltd., Wuhan (CN)

(72) Inventor: Wu LI, (US)

(21) Appl. No.: 16/611,216

(22) PCT Filed: Apr. 25, 2019
(86) PCT No.: PCT/CN2019/084234

§ 371 Date: Nov. 6, 2019

(51) Int. Cl. G06F 3/044; C23C 14/34; G03F 7/20

(52) U.S. Cl. CPC G06F 3/0445; G06F 2203/04103; G03F 7/2006; C23C 14/34

(57) ABSTRACT

The present disclosure provides a touch screen assembly, a method of manufacturing a touch screen assembly and a touch device, including a first protective layer, a conductive layer, and a second protective layer which are sequentially stacked from bottom to top, wherein an upper surface of the conductive layer is provided with a rough structure, the upper surface of the conductive layer is in contact with the second protective layer, the rough structure including a plurality of first grooves regularly arranged, and the rough structure is used for diffusely reflecting and/or scattering an incident light when the incident light illuminates the conductive layer through the second protective layer.

### FIELD OF INVENTION

The present disclosure relates to the field of display technology, in particular, to touch screen assembly, method of manufacturing touch screen assembly and touch device.

### BACKGROUND OF INVENTION

Recently, the development of touch display technology has advanced by leaps and bounds, and users can directly operate on touch displays, so more and more attention and applications have been received.

In the prior art, a touch display including a touch screen attached to the display panel, the touch screen has function of touch control. The touch screen includes a capacitive sensor, which a main structure, including sensing lines crisscross the driving lines, and an insulating layer interposed therebetween. When a finger or other object approaches or touches the touch screen, capacitance between the driving lines and the sensing lines is affected. By detecting a change in capacitance between the driving line and the sensing, the position of the touch point can be detected. One mainstream touch screen structure basically includes the same layer of the driving line and the sensing line, where one of the touch screen structure adopts a metal bridge or an indium tin oxide (ITO) bridge to connect each other. However, the metal bridge structure is easily to cause whitening phenomenon of the metal connecting line under illumination, affecting transmittance and display quality.

Therefore, it is necessary to solve the issues of the prior art.

### SUMMARY OF INVENTION

The present disclosure provides a touch screen assembly, a method of manufacturing touch screen assembly and a touch device, which can reduce whitening phenomenon, improve transmittance and display quality.

In first aspect, an embodiment of the present disclosure provides a touch screen assembly, including:

a screen including a first protective layer, a conductive layer, and a second protective layer which are sequentially stacked from bottom to top; wherein

an upper surface of the conductive layer is provided with a rough structure, the upper surface of the conductive layer is in contact with the second protective layer, the rough structure is used for diffusely reflecting and/or scattering an incident light when the incident light illuminates the conductive layer through the second protective layer.

In the touch screen assembly of the present disclosure, there are spaces between adjacent ones of the plurality of first grooves for carrying the second protective layer

In the touch screen assembly of the present disclosure, a cross-sectional shape of the plurality of regularly arranged first grooves is sawtooth-shaped.

In the touch screen assembly of the present disclosure, a cross-sectional shape of each of the first grooves that is sawtooth-shaped is at least one of a triangle, a rectangle, or an arc.

In the touch screen assembly of the present disclosure, the first grooves each have a horizontal width of 50 nanometers to 5 micrometers, and a vertical depth of 10 nanometers to 50 nanometers.

In the touch screen assembly of the present disclosure, the rough structure further including:

a plurality of second grooves regularly arranged, and the plurality of second grooves are crisscross with the plurality of first grooves.

In the touch screen assembly of the present disclosure, the first protective layer has a vertical thickness from 10 nanometers to 40 nanometers, the second protective layer has a vertical thickness from 10 nanometers to 50 nanometers, and the conductive layer has a vertical thickness from 50 nanometers to 400 nanometers.

In second aspect, an embodiment of the present disclosure further provides a method of manufacturing a touch screen assembly, including:

using an evaporation method to form a first protective layer;

depositing a conductive layer on the first protective layer, wherein the conductive layer is patterned to form a rough structure on the conductive layer;

and depositing a second protective layer on the rough structure to form the touch screen assembly;

wherein the rough structure comprising a plurality of first grooves arranged regularly, the rough structure is used for diffusely reflecting and/or scattering an incident light when the incident light illuminates the conductive layer through the second protective layer.

In the method of manufacturing the touch screen assembly of the present disclosure, the patterning process is at least one of a plasma sputtering process, an etching process, or a laser lithography process.

In third aspect, an embodiment of the present disclosure further provides a touch device, including a housing and a touch screen assembly, the touch screen assembly disposed on the housing, the touch screen assembly including:

a first protective layer, a conductive layer, and a second protective layer which are sequentially stacked from bottom to top; wherein

an upper surface of the conductive layer is provided with a rough structure, the upper surface of the conductive layer is in contact with the second protective layer, the rough structure comprising a plurality of first grooves regularly arranged, and the rough structure is used for diffusely reflected and/or scattered the incident light when the incident light illuminates the conductive layer through the second protective layer, wherein material of the first protective layer and the second protective layer comprising molybdenum, molybdenum oxide or molybdenum nitride, material of the conductive layer is metal material that functions as conductive material.

In the touch device of the present disclosure, there are spaces between adjacent ones of the plurality of first grooves for carrying the second protective layer.

In the touch device of the present disclosure, a cross-sectional shape of the plurality of regularly arranged first grooves is sawtooth-shaped.

In the touch device of the present disclosure, a cross-sectional shape of each of the first grooves that is sawtooth-shaped is at least one of a triangle, a rectangle, or an arc.

In the touch device of the present disclosure, the first grooves each have a horizontal width of 50 nanometers to 5 micrometers, and a vertical depth of 10 nanometers to 50 nanometers.

In the touch device of the present disclosure, the rough structure further including:

a plurality of second grooves regularly arranged, and the plurality of second grooves are crisscross with the plurality of first grooves.

In the touch device of the present disclosure, the first protective layer has a vertical thickness from 10 nanometers to 40 nanometers, the second protective layer has a vertical thickness from 10 nanometers to 50 nanometers, and the conductive layer has a vertical thickness from 50 nanometers to 400 nanometers.

The present disclosure provides a touch screen assembly, including a first protective layer, a conductive layer, and a second protective layer which are sequentially stacked from bottom to top; wherein an upper surface of the conductive layer is provided with a rough structure, the upper surface of the conductive layer is in contact with the second protective layer, the rough structure is used for diffusely reflecting and/or scattering an incident light when the incident light illuminates the conductive layer through the second protective layer. Therefore, reduce whitening phenomenon, improve transmittance and display quality.

### DESCRIPTION OF DRAWINGS

The accompanying figures to be used in the description of embodiments of the present invention will be described in brief to more clearly illustrate the technical solutions of the embodiments. Obviously, the accompanying figures described below are only part of the embodiments of the present invention, from which figures those skilled in the art can derive further figures without making any inventive efforts.

FIG. 1 is a schematic diagram showing a structure of a touch device according to an embodiment of the present disclosure.

FIG. 2 is a schematic diagram showing a first structure of a touch screen assembly according to an embodiment of the present disclosure.

FIG. 3 is a schematic diagram showing a second structure of a touch screen assembly according to an embodiment of the present disclosure.

FIG. 4 is a schematic diagram showing a third structure of a touch screen assembly according to an embodiment of the present disclosure.

FIG. 5 is a schematic diagram showing a fourth structure of a touch screen assembly according to an embodiment of the present disclosure.

FIG. 6 is a schematic diagram showing a fifth structure of a touch screen assembly according to an embodiment of the present disclosure.

FIG. 7 is a flowchart of a method of manufacturing the touch screen assembly according to an embodiment of the present disclosure.

### DETAILED DESCRIPTION OF PREFERRED EMBODIMENTS

The following description of the various embodiments is provided to clearly and completely describe the technical solutions in the embodiments of the present disclosure with the accompanying drawings. Obviously, the described embodiments are only a part of the embodiments of the present disclosure. Based on the embodiments of the present disclosure, those embodiments which make from the skilled in the art without any inventive efforts are within the scope of the present disclosure.

In the prior art, the metal bridge is generally a molybdenum—aluminum—molybdenum structure, wherein the aluminum provides conductive function in the intermediate layer, and the molybdenum is divided into upper layer and lower layer, to reduce the contact resistance and protect the aluminum layer. Wherein a thickness of molybdenum—aluminum—molybdenum layer is typically formed at 30 nanometers, 250 nanometers, and 20 nanometers, respectively. Because thickness of the aluminum is 250 nanometers, the optical property of the aluminum layer is consistent with bulk aluminum, therefore the reflectivity of visible range is as high as 88%, which results in the metal bridge part having a larger reflectance than the part without the metal bridge around. At a certain angle, it can be seen tiny bright spots regularly arranged on the display screen, the tiny bright spots are the light reflected from the metal bridge.

An embodiment of the present disclosure provides a touch device, including: a housing and a touch screen assembly, the touch screen assembly disposed on the housing, the touch screen assembly including:

a first protective layer, a conductive layer, and a second protective layer which are sequentially stacked from bottom to top; wherein

an upper surface of the conductive layer is provided with a rough structure, the upper surface of the conductive layer is in contact with the second protective layer, the rough structure comprising a plurality of first grooves regularly arranged, and the rough structure is used for diffusely reflected and/or scattered the incident light when the incident light illuminates the conductive layer through the second protective layer, wherein material of the first protective layer and the second protective layer comprising molybdenum, molybdenum oxide or molybdenum nitride, material of the conductive layer is metal material that acts as conductive material.

There are spaces between adjacent ones of the plurality of first grooves for carrying the second protective layer.

A cross-sectional shape of the plurality of regularly arranged first grooves is sawtooth-shaped.

A cross-sectional shape of each of the first grooves that is sawtooth-shaped is at least one of a triangle, a rectangle, or an arc.

The first grooves each have a horizontal width of 50 nanometers to 5 micrometers, and a vertical depth of 10 nanometers to 50 nanometers.

The rough structure further including a plurality of second grooves regularly arranged, and the plurality of second grooves are crisscross with the plurality of first grooves.

The rough structure further including a plurality of second grooves regularly arranged, and the plurality of second grooves are crisscross with the plurality of first grooves.

The first protective layer has a vertical thickness from 10 nanometers to 40 nanometers, the second protective layer has a vertical thickness from 10 nanometers to 50 nanometers, and the conductive layer has a vertical thickness from 50 nanometers to 400 nanometers.

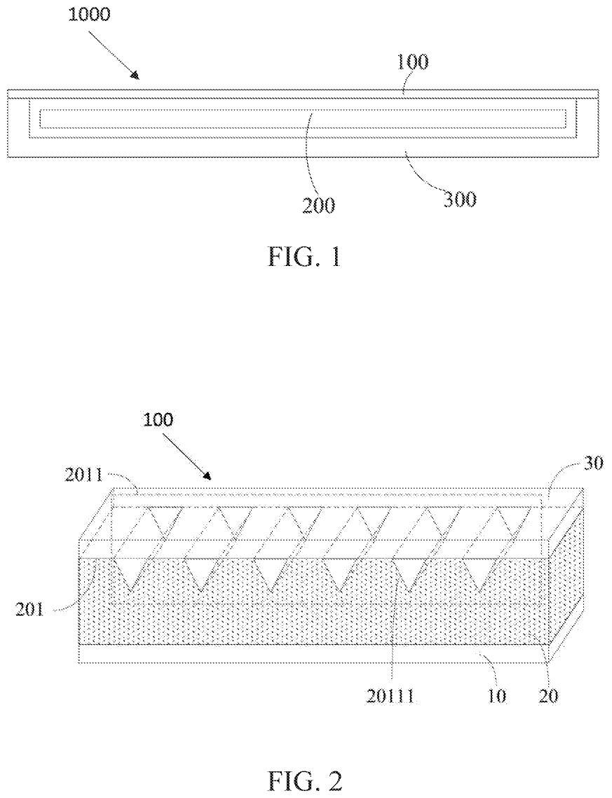

Please refer to FIG. 1, where FIG. 1 is a schematic diagram showing a structure of a touch device 1000 according to an embodiment of the present disclosure. The touch device 100 can include a touch screen assembly 100, a control circuit 200, and a housing 300. It should be noted that the touch device 1000 shown in FIG. 1 is not limited to the above content, and may further include other devices, such as a camera, an antenna structure, a pattern unlocking module, and the like.

The touch screen assembly 100 is disposed on the housing 200.

In some embodiments, the touch screen assembly 100 can be secured to the housing 200, the touch screen assembly 100 and the housing 300 form a confined space to accommodate components such as the control circuit 200.

In some embodiments, the housing 300 can be made of a flexible material, such as a plastic housing or a silicone housing.

The control circuit 200 is installed in the housing 300. The control circuit 200 can be a main board of the touch device 1000. The control circuit 200 can be integrated with one, two or more of the functional components including a battery, an antenna structure, a microphone, a speaker, a headphone interface, a universal serial bus interface, a camera, a distance sensor, an ambient light sensor, a receiver, and a processor.

The touch screen assembly 100 is mounted in the housing 300, and at the same time, the touch screen assembly 100 is electrically connected to the control circuit 200 to form a display surface of the touch device 1000. The touch screen assembly 100 can include a display area and a non-display area. The display area can be used to display a screen of the touch device 1000 or provide a user to perform touch manipulation or the like. This non-display area can be used to set various functional components.

Please refer to FIG. 2, where FIG. 2 is a schematic diagram showing a first structure of a touch screen assembly according to an embodiment of the present disclosure. A touch screen assembly 100 includes a first protective layer 10, a conductive layer 20 and a second protective layer 30 which are sequentially stacked from bottom to top.

An upper surface 201 of the conductive layer 20 is provided with a rough structure 2011, the upper surface 201 of the conductive layer 20 is in contact with the second protection layer 30, and the rough structure 2011 includes a plurality of first grooves 20111 regularly arranged. The rough structure 2011 is used for diffusely reflecting and/or scattering an incident light when the incident light illuminates the conductive layer 20 through the second protective layer 30.

The materials of the first protective layer 10 and the second protective layer 30 are generally molybdenum, molybdenum oxide or molybdenum nitride. The material of the conductive layer 20 is generally a metal material that functions as conductive material, for example, aluminum metal. A first protective layer 10 and the second protective layer 30 are function to reduce the contact resistance and protect the conductive layer 20.

Providing the rough structure 2011 on a surface of the conductive layer 20 can diffusely reflecting and/or scattering an incident light when the incident light illuminates the conductive layer 20 through the second protective layer 30, preventing the conductive layer 20 to produce light under the illumination of the incident light. The incident light including sunlight or other external light.

The rough structure 2011 includes a plurality of first grooves 20111 regularly arranged. By designing the plurality of first grooves 20111, the incident light can be diffused reflection and/or scattering when the incident light illuminates the upper surface 201 of the conductive layer 20.

In some embodiments, the first protective layer 10 has a vertical thickness from 10 nanometers (nm) to 40 nanometers, the second protective layer 30 has a vertical thickness from 10 nanometers to 50 nanometers, and the conductive layer 20 has a vertical thickness from 50 nanometers to 400 nanometers.

An embodiment of the present disclosure provides a touch screen assembly 100, including: a first protective layer 10, a conductive layer 20 and a second protective layer 30 which are sequentially stacked from bottom to top; wherein the upper surface 201 of the conductive layer 20 is provided with the rough structure 2011, the upper surface 201 of the conductive layer 20 is in contact with the second protective layer 30, the rough structure 2011 including a plurality of first grooves 20111 regularly arranged, the rough structure 2011 is used for diffusely reflecting and/or scattering an incident light when the incident illuminates the conductive layer 20 through the second protective layer 30. Thereby reducing whitening phenomenon, and improving transmittance and display quality.

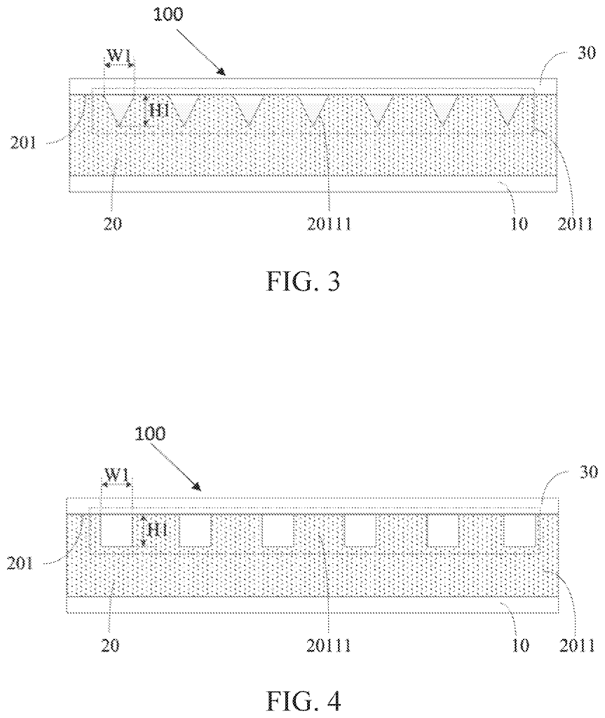

In some embodiments, as shown in FIG. 3, FIG. 3 is a schematic diagram showing a second structure of a touch screen assembly according to an embodiment of the present disclosure. Wherein, there are spaces between adjacent ones of the plurality of first grooves 20111 for carrying the second protective layer 30.

In some embodiments, a cross-sectional shape of the plurality of regularly arranged first grooves 20111 is sawtooth-shaped.

Specifically, the plurality of first grooves 20111 may be formed with a patterning process of the conductive layer 20, the patterning includes but not limited to a plasma sputtering process, an etching process, or a laser lithography process.

In some embodiments, the first grooves each have a horizontal width W1 of 50 nanometers to 5 micrometers, and a vertical depth H1 of 10 nanometers to 50 nanometers.

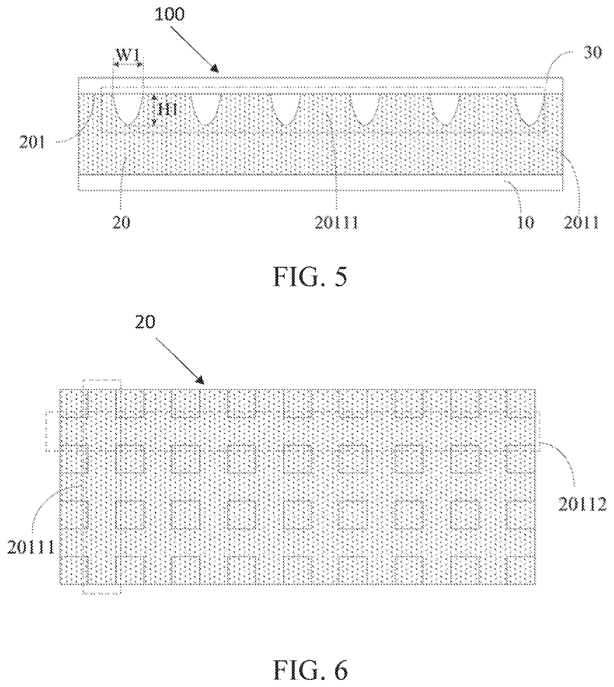

Specifically, please refer FIG. 4 and FIG. 5, FIG. 4 is a schematic diagram showing a third structure of the touch screen assembly according to an embodiment of the present disclosure, FIG. 5 is a schematic diagram showing a fourth structure of a touch screen assembly according to an embodiment of the present disclosure.

A cross-sectional shape of each of the first grooves 20111 that is sawtooth-shaped is at least one of a triangle, a rectangle, or an arc.

Of course, the cross-sectional shape of the first groove 20111 forming the sawtooth-shape is not limited to the above-mentioned several shapes, and may be other shapes, which will not be described herein.

In some embodiments, as shown in FIG. 6, FIG. 6 is a schematic diagram showing a fifth structure of a touch screen assembly according to an embodiment of the present disclosure. FIG. 6 is a top view of the conductive layer 20.

The rough structure 2011 further includes:

a plurality of second grooves 20112 regularly arranged, the plurality of second grooves 20112 are crisscross with the plurality of first grooves 20111.

It can be understood that the crisscross is the plurality of second grooves 20112 intersects with the plurality of first grooves 20111. FIG. 6 shows an embodiment that the plurality of second grooves 20112 perpendicularly intersects with the plurality of first grooves 20111. By crisscross arrangement the plurality of second grooves 20112 with the plurality of first grooves 20111, a mesh-like of the rough structure 2011 can be formed. For example, a cross-sectional shape of the plurality of regularly arranged second grooves 20112 may also is sawtooth-shaped, wherein a cross-sectional shape of each of the first grooves 20111 and a cross-sectional shape of each of the second grooves 20112 include but are not limited to a triangle, a rectangular or an arc. The cross-sectional shape of each of the first groove 20111 and the cross-sectional shape of each of second groove 20112 may be same or different, and it is not limited herein.

An embodiment of the present disclosure provides the touch screen assembly 100, including: a first protective layer 10, a conductive layer 20 and a second protective layer 30 which are sequentially stacked from bottom to top; wherein the upper surface 201 of the conductive layer 20 is provided with the rough structure 2011, the upper surface 201 of the conductive layer 20 is in contact with the second protective layer 30, the rough structure 2011 including a plurality of first grooves 20111 regularly arranged, the rough structure 2011 is used for diffusely reflecting and/or scattering an incident light when the incident illuminates the conductive layer 20 through the second protective layer 30, thereby reducing whitening phenomenon, and improving transmittance and display quality.

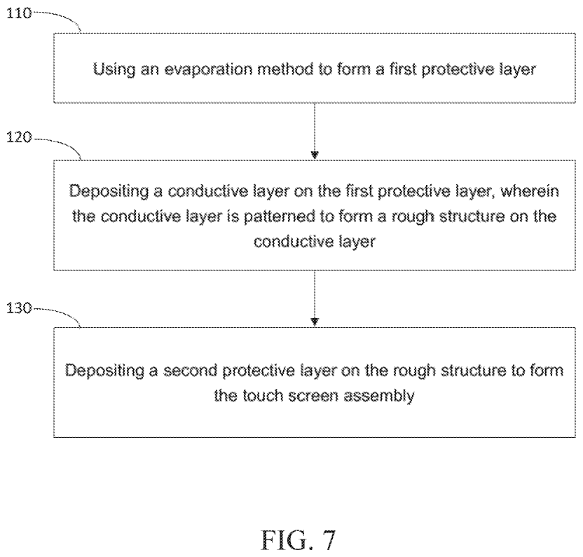

An embodiment of the present disclosure further provides a method of manufacturing a touch screen assembly for manufacturing the touch screen assembly as described above. Please refer to FIG. 7, FIG. 7 is a flowchart of a method of manufacturing the touch screen assembly according to an embodiment of the present disclosure. The method of manufacturing the display screen assembly includes:

110, using an evaporation method to form a first protective layer;

120, depositing a conductive layer on the first protective layer, wherein the conductive layer is patterned to form a rough structure on the conductive layer;

130, depositing a second protective layer on the rough structure to form the touch screen assembly;

The rough structure comprising a plurality of first grooves arranged regularly, the rough structure is used for diffusely reflecting and/or scattering an incident light when the incident light illuminates the conductive layer through the second protective layer.

In some embodiments, the patterning process is at least one of a plasma sputtering process, an etching process, or a laser lithography process.

In the above embodiments, the descriptions of the various embodiments are different, and the details that are not detailed in a certain embodiment can be referred to the related descriptions of other embodiments.

The embodiments of the touch screen assembly, the method for preparing the touch screen assembly and the touch device provided by the present disclosure are described in detailed in the description above. The principles and implementation manners of the present disclosure are described with specific embodiments. The description of the above embodiments is only used for helping understand the technical solutions of the present disclosure. It should be understood by those skilled in the art that the technical solutions described in the above embodiments may be modified, or some of the technical features may be equivalently replaced. The modifications or replacements do not deviate from the essence of the corresponding technical solutions of various embodiments of the present disclosure.

What is claimed is:

1. A touch screen assembly, comprising:
a first protective layer, a conductive layer, and a second protective layer which are sequentially stacked from bottom to top;
wherein an upper surface of the conductive layer is provided with a rough structure, the upper surface of the conductive layer is in contact with the second protective layer, the rough structure comprises a plurality of first grooves regularly arranged, and the rough structure is used for diffusely reflecting and/or scattering an incident light when the incident light illuminates the conductive layer through the second protective layer.

2. The touch screen assembly of claim 1, wherein there are spaces between adjacent ones of the plurality of first grooves for carrying the second protective layer.

3. The touch screen assembly of claim 2, wherein a cross-sectional shape of the plurality of regularly arranged first grooves is sawtooth-shaped.

4. The touch screen assembly of claim 3, wherein a cross-sectional shape of each of the first grooves that is sawtooth-shaped is at least one of a triangle, a rectangle, or an arc.

5. The touch screen assembly of claim 4, wherein the first grooves each have a horizontal width of 50 nanometers to 5 micrometers, and a vertical depth of 10 nanometers to 50 nanometers.

6. The touch screen assembly of claim 1, wherein the rough structure further comprises:
a plurality of second grooves regularly arranged, and the plurality of second grooves crisscross with the plurality of first grooves.

7. The touch screen assembly of claim 1, wherein the first protective layer has a vertical thickness from 10 nanometers to 40 nanometers, the second protective layer has a vertical thickness from 10 nanometers to 50 nanometers, and the conductive layer has a vertical thickness from 50 nanometers to 400 nanometers.

8. A method of manufacturing a touch screen assembly, comprising:
using an evaporation method to form a first protective layer;
depositing a conductive layer on the first protective layer, wherein the conductive layer is patterned to form a rough structure on the conductive layer; and
depositing a second protective layer on the rough structure to form the touch screen assembly;
wherein the rough structure comprising a plurality of first grooves arranged regularly, the rough structure is used for diffusely reflecting and/or scattering an incident light when the incident light illuminates the conductive layer through the second protective layer.

9. The method of manufacturing the touch screen assembly according to claim 8, wherein the patterning process is at least one of a plasma sputtering process, an etching process, or a laser lithography process.

10. A touch device, comprising a housing and a touch screen assembly, the touch screen assembly disposed on the housing, the touch screen assembly comprising:
a first protective layer, a conductive layer, and a second protective layer which are sequentially stacked from bottom to top;
wherein an upper surface of the conductive layer is provided with a rough structure, the upper surface of the conductive layer is in contact with the second protective layer, the rough structure comprising a plurality of first grooves regularly arranged, and the rough structure is used for diffusely reflected and/or scattered the incident light when the incident light illuminates the conductive layer through the second protective layer, wherein material of the first protective layer and the second protective layer comprising molybdenum, molybdenum oxide or molybdenum nitride, material of the conductive layer is metal material that acts as conductive material.

11. The touch device of claim 10, wherein there are spaces between adjacent ones of the plurality of first grooves for carrying the second protective layer.

12. The touch device according to claim 11, wherein a cross-sectional shape of the plurality of regularly arranged first grooves is sawtooth-shaped.

13. The touch device according to claim 12, wherein a cross-sectional shape of each of the first grooves that is sawtooth-shaped is at least one of a triangle, a rectangle, or an arc.

14. The touch device of claim 13, wherein the first grooves each have a horizontal width of 50 nanometers to 5 micrometers, and a vertical depth of 10 nanometers to 50 nanometers.

15. The touch device of claim 10, wherein the rough structure further comprising:
a plurality of second grooves regularly arranged, and the plurality of second grooves are crisscross with the plurality of first grooves.

16. The touch device of claim 10, wherein the first protective layer has a vertical thickness from 10 nanometers to 40 nanometers, the second protective layer has a vertical thickness from 10 nanometers to 50 nanometers, and the conductive layer has a vertical thickness from 50 nanometers to 400 nanometers.
